(19) United States
(12) Patent Application Publication
(10) Pub. No.: US 2006/0267142 A1
(43) Pub. Date: Nov. 30, 2006

(54) Capacitor device, semiconductor devioce, and setting method of terminal capacitance of pad electrode thereof

(75) Inventor: Ken Ota, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/439,193

(22) Filed: May 24, 2006

(30) Foreign Application Priority Data
May 25, 2005 (JP) 2005-153112

(51) Int. Cl. H01L 21/8242

(52) U.S. Cl. 257/532; 438/239

(57) ABSTRACT

A capacitor device comprising: a first wiring region disposed at a predetermined location in a wiring layer on a semiconductor substrate, a second wiring region disposed in a vicinity of the first wiring region and insulated from the first wiring region, at least one first via formed by embedding conductive material in an opening of the first wiring region and electrically connected to the first wiring region; and at least one second via formed by embedding conductive material in an opening of the second wiring region and electrically connected to the second wiring region, wherein the first via and the second via are disposed so that side surfaces thereof are opposed to each other with an insulating film therebetween to form a capacitor.

### BACKGROUND OF THE INVENTION

1. Field of the Invention

This invention relates to a capacitor device included in a semiconductor device and a semiconductor device having a pad electrode formed on a semiconductor substrate, and particularly relates to a semiconductor device capable of setting a desired terminal capacitance of the pad electrode.

2. Related Art

Recently, semiconductor devices such as DRAM and the like have a configuration in which high-speed signals are transmitted between the internal circuits and the outside. Therefore, if the terminal capacitance of the pad electrode as a terminal electrode of the semiconductor device is large, defects occur such as reduction in transmission speed of signals, and the range of terminal capacitance values for the pad electrode is standardized. Therefore, the configuration of the pad electrode of the semiconductor device is generally provided with a capacitor device which can be set for desired terminal capacitance, and particularly, a pad electrode structure which enables adjustments of the capacitance value of the terminal capacitance is often adopted. As the capacitor device for connecting the pad electrode, a configuration using a gate capacitance of a MOS transistor structure and another configuration using a diffusion layer capacitance are typically known.

The capacitor device using the gate capacitance has an advantage in that the capacitance per unit area can be made large. However, since its gate oxide film has a structure susceptible to electrostatic breakdown, the capacitor device needs to be connected to the pad electrode through a protection resistor. Generally, in order to lower the effective input resistance (Ri) defined for the pad electrode, it is desirable that the protection resistor inserted in series is minimized. However, in the case of adopting the capacitor device using the gate capacitance, it is inevitable that the effective input resistance is increased by inserting the protection resistor capable of preventing the electrostatic breakdown. Further, to adjust the capacitance value of the capacitor device using the gate capacitance, connections are switched between a plurality of capacitor devices each having a predetermined MOS transistor structure, and it is thus difficult to make fine adjustments to the capacitance value.

Meanwhile, the capacitor device using the diffusion layer capacitance has a structure that does not undergo electrostatic breakdown. However, when the diffusion layer capacitance is formed, the effective input resistance is increased as a result of substrate resistance and contact resistance existing in the path. Further, the diffusion layer capacitance which is a discharge path needs to be spaced some distance apart from internal devices in the semiconductor device, and the space efficiency degrades in the semiconductor device.

Furthermore, as a pad electrode structure capable of setting the terminal capacitance of the pad electrode, a configuration in which comb-shaped wiring is disposed around the pad electrode is proposed (see JP 2004-247659). However, in such a configuration, it is not possible to sufficiently secure the area opposed between the pad electrode and the comb-shaped wiring, and it is difficult to obtain the desired terminal capacitance.

### BRIEF SUMMARY OF THE INVENTION

It is an object of the present invention to provide a semiconductor device and the like having a pad electrode structure which has excellent space efficiency without increasing the effective input resistance in securing suitable terminal capacitance of the pad electrode, and which enables fine adjustment of the terminal capacitance.

An aspect of the present invention is a capacitor device comprising a first wiring region disposed at a predetermined location in a wiring layer on a semiconductor substrate, a second wiring region disposed in a vicinity of said first wiring region and insulated from said first wiring region, at least one first via formed by embedding conductive material in an opening of said first wiring region and electrically connected to said first wiring region; and at least one second via formed by embedding conductive material in an opening of said second wiring region and electrically connected to said second wiring region, wherein said first via and said second via are disposed so that side surfaces thereof are opposed to each other with an insulating film therebetween to form a capacitor.

According to the aspect of the capacitor device, a conductive portion including the first wiring region and the first via and a conductive portion including the second wiring region and the second via act as a capacitor with insulating films therebetween. In this case, the opposite area in proportion to the capacitance value is mainly determined by the arrangement of side surfaces of the first and second vias opposite to each other. Therefore, by increasing the via depth in the vertical direction in addition to the size in the horizontal direction, the opposite area is increased and a sufficient capacitance value can be obtained. Accordingly, it is possible to form a desired capacitor with ease and suppress the effect of series resistance components. Further, it is possible to appropriately adjust the opposite area of the vias, and the capacitance value of the capacitor device can be freely adjusted.

In the capacitor device of the present invention, a plurality of said first vias may be arranged in line in said first wiring region along a longitudinal direction thereof, and a plurality of said second vias may be arranged in line in said second wiring region along a longitudinal direction thereof.

In the capacitor device of the present invention, a single said first via formed in a slit shape may be disposed in said first wiring region, and a single said second via formed in a slit shape may be disposed in said second wiring region.

An aspect of the present invention is a semiconductor device comprising a pad electrode formed on a semiconductor substrate, a surrounding wiring disposed in a vicinity of said pad electrode and insulated from said pad electrode to be connected to an external fixed potential, at least one first via formed extending downward by embedding conductive material in an opening in a vicinity of an outer edge of said pad electrode and electrically connected to said pad electrode and at least one second via formed extending downward by embedding conductive material in an opening of said surrounding wiring and electrically connected to said surrounding wiring, wherein said first via and said second via are disposed so that side surfaces thereof are opposed to each other with an insulating film therebetween to form a capacitor.

According to the aspect of the semiconductor device, a conductive portion including the pad electrode and the first via and a conductive portion including the surrounding wiring and the second via act as a capacitor with insulating films therebetween, and it is possible to set a terminal capacitance of the pad electrode. In this case, the opposite area of the conductive portions is in proportion to the terminal capacitance and mainly determined by the arrangement of side surfaces of the first and second vias opposite to each other. Therefore, by increasing the via depth in the vertical direction in addition to the size in the horizontal direction, the opposite area is increased and a sufficient capacitance value can be obtained. Accordingly, it is possible to secure a desired terminal capacitance of the pad electrode freely and to limit the effective input resistance to a low value because of the absence of series resistance components, and the extra space is not necessary for a discharge path and the like. Further, by appropriately adjusting the opposite area of the vias, the terminal capacitance of the pad electrode can be freely adjusted within a predetermined range.

In the semiconductor device of the present invention, said surrounding wiring may be formed in a band shape with a predetermined width so as to surround an entire said pad electrode

In the semiconductor device of the present invention, a plurality of said first vias may be arranged in line along an outer edge of said pad electrode, and a plurality of said second vias may be arranged in line in said surrounding wiring along a longitudinal direction thereof.

In the semiconductor device of the present invention, a single said first via formed in a slit shape may be disposed in said pad electrode, and a single said second via formed in a slit shape may be disposed in said surrounding wiring.

The semiconductor device of the present invention may further comprises a pad connecting portion disposed around said pad electrode and electrically connected to said pad electrode, wherein said at least one first via is formed in both said pad electrode and said surrounding wiring, and wherein said surrounding wiring and said pad connecting portion form a plurality of lines arranged alternately around said pad electrode.

An aspect of the present invention is a setting method of a terminal capacitance of said pad electrode of said semiconductor device, which is capable of selectively setting said terminal capacitance, wherein cutting said surrounding wiring having said at least one second via at cutting positions set corresponding to a desired terminal capacitance so as to form a cut wiring portion electrically disconnected from said surrounding wiring and to be in a state in which said cut wiring portion and each said second via connected to said cut wiring portion are not connected to said external fixed potential.

Further, an aspect of the present invention is setting method of a terminal capacitance of said pad electrode of said semiconductor device, which is capable of selectively setting said terminal capacitance, wherein forming a conductive region at a position set corresponding to a desired terminal capacitance in a plate layer under said surrounding wiring so that a via depth of said position of said conductive region is smaller than that of other regions in forming each said second via.

According to the aspect of the setting method, in the case of setting the terminal capacitance of the pad electrode in the semiconductor device of the invention, the terminal capacitance can be freely adjusted during the manufacturing process of the semiconductor device. For the adjustment in this case, various methods can be adopted to decrease the opposite area of the vias, such as cutting the surrounding wiring to form a cut wiring portion in floating-state, forming a conductive region under the surrounding wiring in a plate layer, or the like. Accordingly, as compared with the configuration using the gate capacitance of the MOS transistor structure, it is possible to make finer adjustments with high accuracy corresponding to the desired terminal capacitance.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a plan view of a pad electrode and its surroundings in a semiconductor device of a first embodiment;

FIG. 2 is a cross-sectional view along a line A-A′ in FIG. 1;

FIG. 3 is a plan view of the pad electrode and its surroundings in the semiconductor device of a second embodiment;

FIG. 4 is a plan view of the pad electrode and its surroundings in the semiconductor device of a third embodiment;

FIG. 5 is a cross-sectional view along a line B-B′ in FIG. 4;

FIG. 6 is a plan view of the pad electrode and its surroundings in the semiconductor device of a fourth embodiment;

FIG. 7 is a schematic a cross-sectional view along a line C-C′ in FIG. 6 with respect to DRAM to which the fourth embodiment is applied;

FIG. 8 is a plan view of the pad electrode and its surroundings in the semiconductor device of a fifth embodiment;

FIG. 9 is a schematic cross-sectional view along a line D-D′ in FIG. 8 with respect to DRAM to which the fifth embodiment is applied;

FIG. 10 is a view showing one example of a configuration of the capacitor device of a sixth embodiment; and

FIG. 11 is a view showing the other example of a configuration of the capacitor device of the sixth embodiment.

### DETAILED DESCRIPTION OF THE INVENTION

Preferred embodiments of the present invention will be described below with reference to accompanying drawings. As the embodiments to which the invention is applied, a plurality of embodiments (first to sixth embodiments) with different configurations will be described.

### First Embodiment

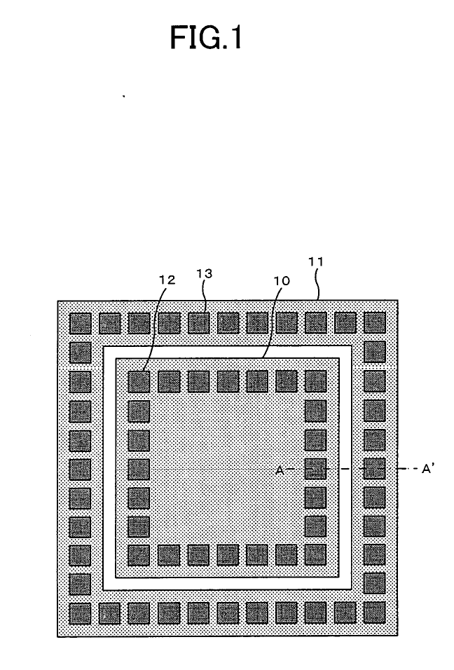

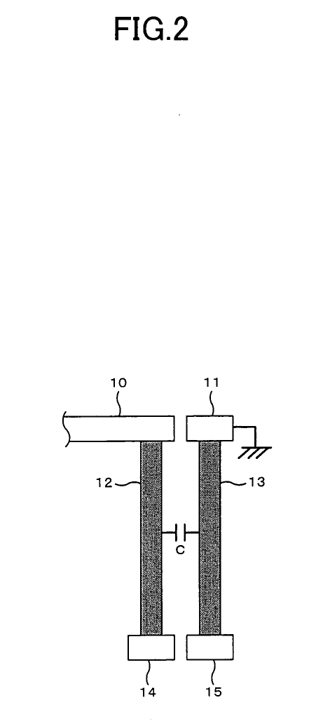

In the first embodiment, the present invention is applied to a semiconductor device in which a pad electrode is formed as an input/output terminal on a semiconductor substrate, based on the configuration of FIGS. 1 and 2. FIG. 1 shows a plan view of the pad electrode and its surroundings in the semiconductor device of the first embodiment, and FIG. 2 shows a cross-sectional view along the line A-A′ in the configuration of FIG. 1. In the semiconductor device of the first embodiment, a rectangular pad electrode 10 and a band-shaped surrounding wiring 11 which surrounds the entire pad electrode 10 are formed. The pad electrode 10 and the surrounding wiring 11 are formed, for example, on an upper aluminum wiring layer of the semiconductor device, and electrically insulated from each other by insulating films spaced a predetermined distance.

The pad electrode 10 is used as a connection terminal for inputting and outputting signals between the semiconductor device and the outside. A bonding wire is bonded on the upper portion of the pad electrode 10, and the pad electrode 10 is connected to one of internal circuits of the semiconductor device through a wiring pattern. The surrounding wiring 11 is formed in a band shape with a predetermined width sandwiched between the rectangular inner circumference and the outer circumference, and is connected to the external fixed potential such as ground of the semiconductor device or the like through a wiring pattern.

In the pad electrode 10, a number of vias 12 arranged in line along the outer edge are formed. In the surrounding wiring 11, a number of vias 13 arranged in line along the longitudinal direction are formed. The vias 12 of the pad electrode 10 and the vias 13 of the surrounding wiring 11 have rectangular cross section with the same size, and are arranged opposite to each other with insulating films therebetween.

As shown in FIG. 2, in the stacking direction of the semiconductor device, the vias 12 in which conductive material is embedded from its opening of the upper pad electrode 10 to a substrate plate 14 are formed, and the vias 13 in which conductive material is embedded from its opening of the upper surrounding wiring 11 to a substrate plate 15 are formed. The vias 12 and the vias 13 are in a positional relationship such that respective side surfaces are disposed opposite to each other with a distance capable of forming appropriate capacitance therebetween. As the conductive material of the vias 12 and 13, tungsten is used, for example. Thus, the via 12 of the pad electrode 10 and the via 13 of the surrounding wiring 11 are disposed opposite to each other sandwiching the insulating films with a predetermined gap to form the capacitance between respective side surfaces with the predetermined via depth and width, and its capacitance value is determined corresponding to the opposite area and the gap distance.

By this means, the entire pad electrode 10 is in a state that terminal capacitance C is inserted between the electrode 10 and the surrounding wiring 11 as shown in FIG. 2. In other words, in the configuration in which the surrounding wiring 11 is connected to ground, the pad electrode 10 is equivalently connected to ground through the terminal capacitance C. In addition, the external fixed potential to which the surrounding wiring 11 is connected is not limited to the ground, but may be other external fixed potential such as a power supply voltage or the like. The ground and the power supply voltage are connected with sufficiently low capacitance (low impedance), and thus, is equivalent to each other as the capacitance of the pad electrode 10.

In the first embodiment, the value of the terminal capacitance C is determined depending on design conditions such as the size of both vias 12 and 13, the number thereof, the distance therebetween and the like. The terminal capacitance C becomes larger as the number and size of the vias 12 and 13 increases, but is limited by the entire size of the pad electrode 10. The terminal capacitance C becomes larger as the depth of the vias 12 and 13 increases, but the distance from the substrate plates 14 and 15 to the pad electrode 10 or the surrounding wiring 11 is limited by restrictions of the semiconductor process. The terminal capacitance C increases as the distance between the vias 12 and the vias 13 decreases, but it is necessary to set a gap distance capable of securing margin such that a short between the adjacent vias 12 and 13 is avoided when forming them. In addition, it is also possible to adjust the capacitance value of the terminal capacitance C of the pad electrode 10 appropriately in the manufacturing process of the semiconductor device, which will be specifically described later.

Although the substrate plates 14 and 15 are provided at lower ends of the vias 12 and 13 in the configuration in FIG. 2, the substrate plates 14 and 15 may not be provided. That is, the lower ends of the vias 12 and 13 are formed in the shape in which the conductive material is embedded, and the vias 12 and 13 are surrounded by the insulating material. In this case, in order for the lower ends of the vias 12 and 13 not to contact the substrate, it is desirable to place a material such as TrN or the like on a lower layer as a stopper for supporting the lower ends of the vias 12 and 13.

### Second Embodiment

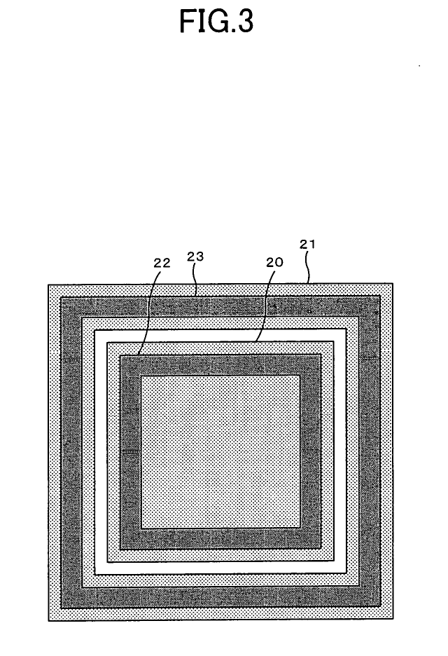

In the second embodiment, the present invention is applied to a semiconductor device in which a pad electrode is formed, based on the configuration of FIG. 3. FIG. 3 shows a plan view of the pad electrode and its surroundings in the semiconductor device of the second embodiment. In the semiconductor device of the second embodiment, a pad electrode 20 and a band-shaped surrounding wiring 21 which surrounds the pad electrode 20 are formed on a semiconductor substrate, and are the same in size and shape as in the first embodiment. Meanwhile, in the second embodiment, a via 22 formed in the pad electrode 20 and a via 23 formed in the surrounding wiring 21 are respectively different in structure from the vias 12 and 13 in the first embodiment.

As shown in FIG. 3, the via 22 of the pad electrode 20 and the via 23 of the surrounding wiring 21 are each formed in the shape of a single slit. That is, it is a feature of the second embodiment that each of vias 22 and 23 is a single continuous region without being divided into a plurality of regions as in the first embodiment. Then, the via 22 of the pad electrode 20 and the via 23 of the surrounding wiring 21 surrounding the via 22 are disposed so that their side surfaces are opposed to each other with an insulating film therebetween over the entire circumference. The cross-sectional structure corresponding to the plan view of FIG. 3 is expressed as in FIG. 2. Further, the surrounding wiring 21 is connected to the external fixed potential such as ground or the like, and in this respect, is the same as in the first embodiment.

In the second embodiment, the terminal capacitance C between the entire pad electrode 20 and the entire surrounding wiring 21 is larger than that in the first embodiment. In other words, assuming that sizes and shapes of the pad electrode 20 and the surrounding wiring 21 and the depth of the vias 22 and 23 are the same conditions as in the configuration of FIG. 1, the opposite area in the width direction of vias 22 and 23 in FIG. 3 can be larger than that in FIG. 1, and the terminal capacitance C correspondingly increases.

Meanwhile, the second embodiment provides the configuration having an advantage in increasing the terminal capacitance C of the pad electrode 20, but the process of forming the pad electrode structure of the second embodiment is more complicated than that of the first embodiment. A plurality of vias 12 and 13 of rectangular cross section as shown in FIG. 1 can be formed relatively easily. However, in forming the vias 22 and 23 of long slit-shaped cross section as shown in FIG. 3, it is more difficult to secure accuracy and the like.

Also in the second embodiment, as in the first embodiment, the value of the terminal capacitance C is determined depending on design conditions. In the configuration of FIG. 3, design conditions of the depth of the vias 22 and 23, the gap distance therebetween and the like have significant effects, and these conditions are set based on the desired terminal capacitance C and limited by restrictions of the semiconductor process.

### Third Embodiment

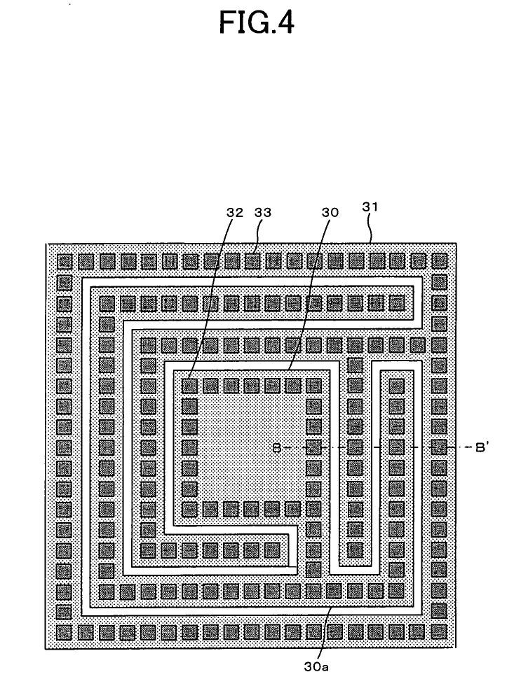

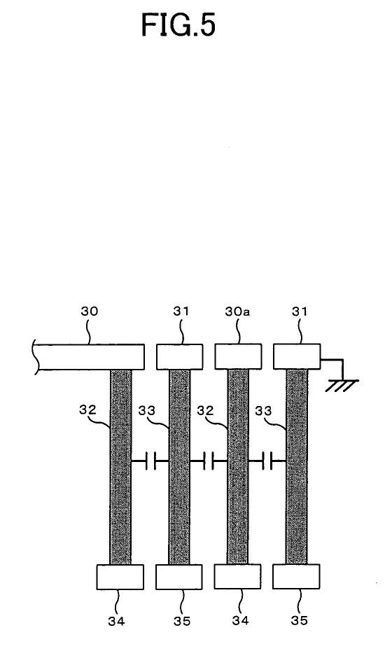

In the third embodiment, the present invention is applied to a semiconductor device in which a pad electrode is formed, based on the configuration of FIGS. 4 and 5. FIG. 4 shows a plan view of the pad electrode and its surroundings in the semiconductor device of the third embodiment, and FIG. 5 shows a cross-sectional view along the line B-B′ in the configuration of FIG. 4. In the semiconductor device of the third embodiment, in addition to a pad electrode 30 and a surrounding wiring 31, on the semiconductor substrate, a pad connecting portion 30a electrically connected to the pad electrode 30 is formed, which is a conductive region attached to one end of the pad electrode 30. The surrounding wiring 31 and the pad connecting portion 30a each have a number of lines and form a plurality of lines arranged alternately around the pad electrode 30. In this case, the pad electrode 30 and the pad connecting portion 30a are insulated from the surrounding wiring 31 by the insulating film, and in this respect, the same as in FIG. 1. Also in this case, the surrounding wiring 31 is connected to the external fixed potential such as ground or the like through the wiring pattern.

A number of vias 32 are formed near the outer edge of the pad electrode 30 and in the pad connecting portion 30a, while a number of vias 33 are formed in the surrounding wiring 31. The vias 32 and 33 have rectangular cross sections with the same size, and their side surfaces are disposed opposite to each other with an insulating film therebetween, as in the vias 12 and 13 in FIG. 1.

As shown in FIG. 5, it is understood that a pattern in which the cross-sectional structure as in FIG. 2 is repeated in the layer direction of the semiconductor is obtained. The vias 32 from the pad electrode 30 or the pad connecting portion 30a to the substrate plate 34 and the vias 33 from the surrounding wiring 31 to the substrate plate 35 are alternately arranged with the same gap distance. In the example of FIG. 5, the vias 32 and the vias 33 are in a relation in which their one side surfaces or both side surfaces are opposed to each other. Accordingly, between the entire pad electrode 30 and the entire surrounding wiring 31, the lines are connected in parallel to increase the opposite area, resulting in a state in which the larger terminal capacitance C is inserted. In the configuration in which the surrounding wiring 31 is connected to ground, the pad electrode 30 is connected to ground through the large terminal capacitance C.

Thus, in the third embodiment, it is possible to obtain large capacitance by increasing the number of lines formed by the pad connecting portion 30a and the surrounding wiring 31. For example, in the example of FIG. 5, two lines of vias 32 and 33, total four lines, are arranged, but it is possible to increase the number of lines being arranged, as long as there is a region in which the lines are arranged around the pad connecting portion 30a. However, in consideration of the increase in the area around the pad connecting portion 30a and the surrounding wiring 31, the terminal capacitance C is desirably set in an appropriate range.

In the example of FIG. 5, as the vias 32 in the pad connecting portion 30a and the vias 33 in the surrounding wiring 31, the configuration of using a number of divided vias of rectangular cross section as in the vias 12 and 13 in FIG. 1 is shown. However, as in the vias 22 and 23 in FIG. 3, the configuration of using a single slit-shaped via can be adopted. The terminal capacitance C of the pad electrode 30 can thereby be set at a larger capacitance value.

### Fourth Embodiment

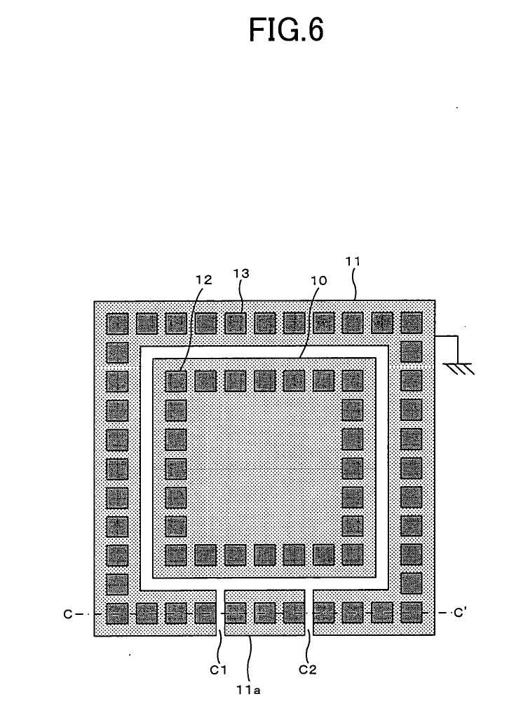

In the fourth embodiment, the present invention is applied to a semiconductor device enabling the terminal capacitance C of the pad electrode 10 to be adjusted during the manufacturing process. Herein, a configuration is described in which the configuration of the first embodiment is assumed and to which a method of adjusting the terminal capacitance C of the pad electrode 10 is added. FIG. 6 shows a plan view of the pad electrode and its surroundings in the semiconductor device of the fourth embodiment, where a cut wiring portion 11a which is obtained by partially cutting the surrounding wiring 11 is formed, in addition to the pad electrode 10, the surrounding wiring 11, and the vias 12 and 13 as in FIG. 1.

In FIG. 6, the band-shaped surrounding wiring 11 is cut at two cutting positions C1 and C2. In this case, the cut wiring portion 11a from the cutting position C1 to the cutting position C2 is electrically disconnected from the surrounding wiring 11 and is in floating state without connection to the external fixed potential. Therefore, the vias 12 in the pad electrode 10 and the vias 13 in the surrounding wiring 11 act as a capacitor with the external fixed potential as in the configuration of FIG. 1. However, the vias 12 in the pad electrode 10 and the vias 13 in the cut wiring portion 11a do not act as a capacitor with the external fixed potential. That is, by cutting at the two cutting positions C1 and C2, the entire terminal capacitance C decreases corresponding to the opposite area of the vias 12 in the pad electrode 10 and the vias 13 in the cut wiring portion 11a.

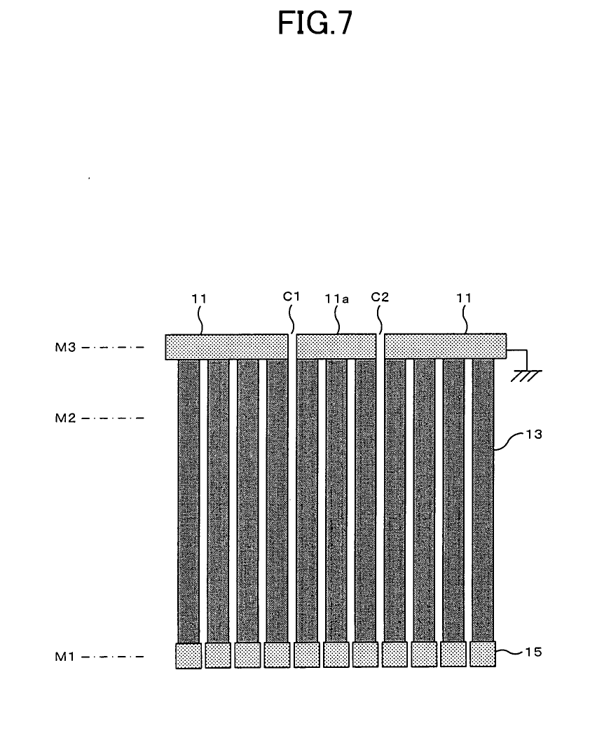

Herein, a specific example of the case in which the semiconductor device of the fourth embodiment is applied to DRAM will be described with reference to FIG. 7. FIG. 7 shows a schematic cross-sectional view along the line C-C′ of FIG. 6 with respect to DRAM to which the fourth embodiment is applied. In the manufacturing process of the DRAM, a structure of MOS transistors (not shown) are formed on the silicon substrate, and a wiring layer M1 made of, for example, tungsten and wiring layers M2 and M3 made of, for example, AlCu are stacked sequentially thereon. Interlayer films made of, for example, SiO2 are stacked and sandwiched between respective wiring layers M1, M2 and M3.

As shown in FIG. 7, in the C-C′ cross section in FIG. 6, the substrate plates 14 (not shown in FIG. 7) of the vias 12 and the substrate plates 15 of the vias 13 are formed in the lower wiring layer M1, and the vias 12 (not shown) and 13 from the upper wiring layer M3 to the lower wiring layer M1 are formed by embedding, for example, tungsten. In this range, wiring to the center wiring layer M2 is not formed. Then, prior to formation of the pad electrode 10 (not shown) and the surrounding wiring 11, a mask is prepared which is cut at the cutting positions C1 and C2 corresponding to a desired capacitance value. Thereby, when the surrounding wiring 11 connected to the vias 13 is formed, the cut wiring portion 11a connected to other vias 13 can be separated at the cutting positions C1 and C2. In this case, as the cutting positions C1 and C2 are placed with larger distance to obtain the wider cut wiring portion 11a, the degree of decrease of the terminal capacitance C becomes larger.

In addition, the fourth embodiment can be applied to the configuration of the first embodiment as described above, but cannot be applied to the configuration of the second embodiment. That is, even if the upper wiring layer M3 is cut, the original capacitance value is maintained because the vias 13 of the surrounding wiring 11 are being joined together. Meanwhile, the fourth embodiment can be applied to the configuration of the third embodiment by setting the cutting positions suitably.

### Fifth Embodiment

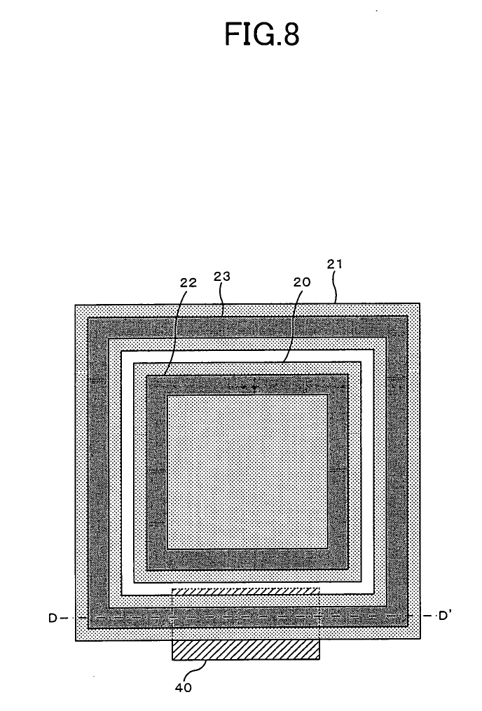

In the fifth embodiment, the present invention is applied to a semiconductor device enabling the terminal capacitance C of the pad electrode 10 to be adjusted during the manufacturing process by a method different from that in the fourth embodiment. Herein, a configuration is described in which the configuration of the second embodiment is assumed and to which a method of adjusting the terminal capacitance C of the pad electrode 20 is added. FIG. 8 shows a plan view of the pad electrode and its surroundings in the semiconductor device of the fifth embodiment, where a plate 40 is formed at a position in a lower layer so as to overlap part of the surrounding wiring 21, in addition to the pad electrode 20, the surrounding wiring 21, and the vias 22 and 23 as in FIG. 2. By thus forming the plate 40, the depth of the via 23 located on the plate 40 can be reduced, thereby decreasing the opposite area of the via 22 of the pad electrode 20 and the via 23 of the surrounding wiring 21, and it is thus possible to reduce the entire terminal capacitance C.

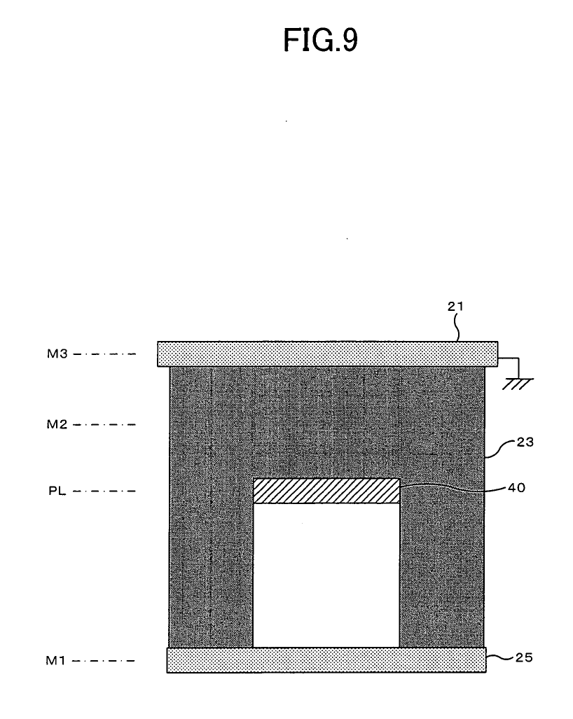

Herein, a specific example of the case in which the semiconductor device of the fifth embodiment is applied to DRAM will be described with reference to FIG. 9. FIG. 9 shows a schematic cross-sectional view along the line D-D′ of FIG. 8 with respect to DRAM to which the fifth embodiment is applied. In addition, while forming methods and materials of the silicon substrate, three wring layers M1, M2 and M3 and interlayer insulating films are the same as those in FIG. 7, a plate layer PL is stacked almost midway between the wiring layers M1 and M2 using, for example, tungsten.

As shown in FIG. 9, in the D-D′ cross section in FIG. 8, after forming the substrate plate (not shown) of the via 22 and a substrate plate 25 of the via 23 in the lower wiring layer M1, the plate 40 is formed at an area in the plate layer PL so as to overlap part of the substrate plate 25. In this state, a mask for forming the plate 40 in the shape and size corresponding to the desired capacitance value of the pad electrode 20 is prepared. Then, wiring to the wiring layer M2 is not formed above the plate layer PL, and prior to formation of the pad electrode 20 and the surrounding wiring 21 in the upper wiring layer M3, the vias 22 and 23 are formed by embedding, for example, tungsten. Thereby, in the via 23, the via depth in a region below which the plate 40 is formed is limited by the plate 40, while the via depth in the other region reaches the lower wiring layer M1. Accordingly, the opposite area of the via 22 of the pad electrode 20 and the via 23 of the surrounding wiring 21 decreases corresponding to the region from the plate 40 to the lower wiring layer M1, and the terminal capacitance C can be reduced. In this case, as the area of the plate 40 overlapping under the surrounding wiring 21 increases, the degree of decrease of the capacitance C increases.

In addition, the fifth embodiment is not limited to applying to the configuration of the second embodiment as described above, but can be applied to the first embodiment and the third embodiment. However, in the case of applying to the third embodiment, it is necessary to form the plate 40 in such a shape which overlaps the surrounding wiring 31 as shown in FIG. 6. Further, the configuration of the fifth embodiment can be applied in a combination with the fourth embodiment.

The fourth and fifth embodiments can be applied in a combination with the configuration using conventional gate capacitance. By thus configuring, for example, the gate capacitance with a desired value and the capacitor based on the pad electrode structure to which the present invention is applied are both connected to the pad electrode 10 in FIG. 6, and it is possible to set the terminal capacitance C using parallel connection thereof. Then, by making fine adjustments to the terminal capacitance C based on the methods of the fourth and fifth embodiments, it is possible to freely adjust the terminal capacitance C finely without limitation of the MOS transistor structure for use in the gate capacitance.

### Sixth Embodiment

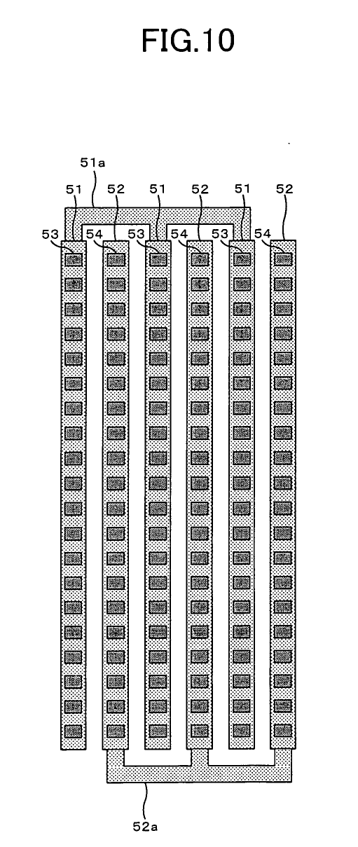

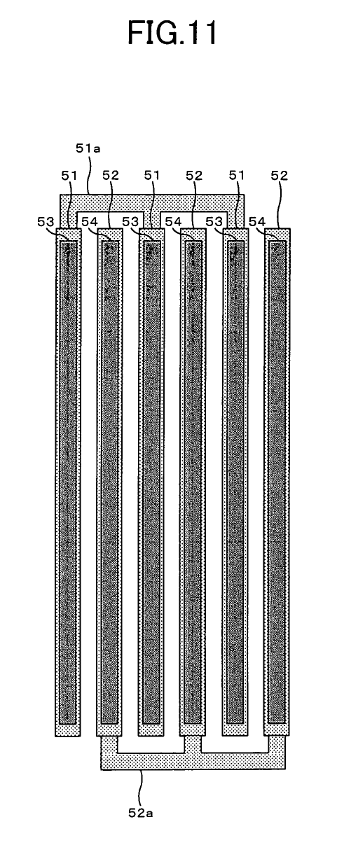

The sixth embodiment differs from the first to fifth embodiments, and the present invention is applied to capacitor devices in general which are formed inside semiconductor devices, without limiting to the pad electrode. FIGS. 10 and 11 are plan views showing examples of a configuration of the capacitor device of the sixth embodiment. First, the capacitor device as shown in FIG. 10 is composed of a first wiring region 51 and a second wiring region 52 each formed in the wiring layer, vias 53 formed in the first wiring region 51 and vias 54 formed in the second wiring region 52.

As shown in FIG. 10, the first wiring region 51 and the second wiring region 52 respectively include long regions disposed opposite to each other with insulating films therebetween. In the first wiring region 51, a plurality of regions are integrally connected through a connection portion 51a at one end, and in the second wiring region 52, a plurality of regions are integrally connected through a connection portion 52a at one end. A number of vias 53 are disposed in line in the first wiring region 51 along the longitudinal direction, while a number of vias 54 are disposed in line in the second wiring region 52 along the longitudinal direction. These vias 53 and 54 have the same shapes as those of the vias 12 and 13 in FIG. 1, their side surfaces are disposed opposite to each other to the substrate plate formed in the lower portion with insulating films therebetween, and the capacitance is formed between their side surfaces.

Meanwhile, in the capacitor device as shown in FIG. 11, the vias 53 in the first wiring region 51 and the vias 54 in the second wiring region 52 are formed in a structure different from that in FIG. 10, in addition to the first wiring region 51 and the second wiring region 52 as in FIG. 10. That is, the vias 53 and 54 are each formed as a single continuous region as in the vias 22 and 23 in FIG. 3. These vias 53 and 54 are disposed so that their side surfaces are opposed to each other to the substrate plate formed in the lower portion with insulating films therebetween, capacitance is formed between their side surfaces, and in this respect, it is the same as in the case of FIG. 10. However, the opposite area is slightly larger than that in FIG. 10, and thus the capacitance between the side surfaces is also larger.

Thus, based on the configuration of FIG. 10 or FIG. 11, it is possible to realize a capacitor device which can be used in a semiconductor device. Then, in the internal circuit of the semiconductor device, it is possible to insert the capacitor into a predetermined portion of the internal circuit by connecting the first wiring region 51 at one end and connecting the second wiring region 52 at the other end each through a wiring pattern (not shown). In this case, since the configuration of FIG. 11 is capable of securing a larger opposite area of the vias 53 and 54 as compared with the configuration of FIG. 10, the configuration has an advantage to obtain a larger capacitance value, but has a higher degree of difficulty in manufacturing as described above.

Although in the foregoing, the present invention is described specifically based on the first to sixth embodiments, the present invention is not limited to the above-mentioned embodiments, and is capable of being carried into practice with various modifications thereof without departing from the scope of the subject matter thereof. For example, the shape of the surrounding wiring 11 (21) of the first (second) embodiment is not limited to the band shape, and can have any shape which is disposed in the vicinity of the pad electrode 10 (20), as long as the shape has a structure capable of forming capacitance between side surfaces thereof. In this case, a plurality of surrounding wirings 11 each connected to the external fixed potential may be disposed around the pad electrode 11 (21). Further, the present invention is not limited to the method as described in the fourth (fifth) embodiment, but such a method may be adopted that adjusts the terminal capacitance using a mask in which the number and/or the size of the vias is changed.

The capacitor device of the present invention can be applied in a combination with the conventional configuration such as a capacitor device using a gate capacitance of a MOS transistor structure or a capacitor device using a diffusion layer capacitance.

Further, the capacitor device of the present invention can be applied to a semiconductor device produced by a damascene process. Particularly, the capacitor device of the present invention can be configured using a structure in which a wiring and a via are formed as a single piece using a dual damascene process.

The present invention is not limited to the above described embodiments, and various variations and modifications may be possible without departing from the scope of the present invention.

This application is based on the Japanese Patent application No. 2005-153112 filed on May 25, 2005, entire content of which is expressly incorporated by reference herein.

What is claimed is:

1. A capacitor device comprising:
a first wiring region disposed at a predetermined location in a wiring layer on a semiconductor substrate,
a second wiring region disposed in a vicinity of said first wiring region and insulated from said first wiring region,
at least one first via formed by embedding conductive material in an opening of said first wiring region and electrically connected to said first wiring region; and
at least one second via formed by embedding conductive material in an opening of said second wiring region and electrically connected to said second wiring region,
wherein said first via and said second via are disposed so that side surfaces thereof are opposed to each other with an insulating film therebetween to form a capacitor.

2. A capacitor device according to claim 1, wherein a plurality of said first vias is arranged in line in said first wiring region along a longitudinal direction thereof, and a plurality of said second vias is arranged in line in said second wiring region along a longitudinal direction thereof.

3. A capacitor device according to claim 1, wherein a single said first via formed in a slit shape is disposed in said first wiring region, and a single said second via formed in a slit shape is disposed in said second wiring region.

4. A semiconductor device comprising:
a pad electrode formed on a semiconductor substrate,
a surrounding wiring disposed in a vicinity of said pad electrode and insulated from said pad electrode to be connected to an external fixed potential,
at least one first via formed extending downward by embedding conductive material in an opening in a vicinity of an outer edge of said pad electrode and electrically connected to said pad electrode; and
at least one second via formed extending downward by embedding conductive material in an opening of said surrounding wiring and electrically connected to said surrounding wiring,
wherein said first via and said second via are disposed so that side surfaces thereof are opposed to each other with an insulating film therebetween to form a capacitor.

5. A semiconductor device according to claim 4, wherein said surrounding wiring is formed in a band shape with a predetermined width so as to surround an entire said pad electrode.

6. A semiconductor device according to claim 4, wherein a plurality of said first vias is arranged in line along an outer edge of said pad electrode, and a plurality of said second vias is arranged in line in said surrounding wiring along a longitudinal direction thereof.

7. A semiconductor device according to claim 4, wherein a single said first via formed in a slit shape is disposed in said pad electrode, and a single said second via formed in a slit shape is disposed in said surrounding wiring.

8. A semiconductor device according to any of claims 4 to 7 further comprising a pad connecting portion disposed around said pad electrode and electrically connected to said pad electrode,
wherein said at least one first via is formed in both said pad electrode and said surrounding wiring, and wherein said surrounding wiring and said pad connecting portion form a plurality of lines arranged alternately around said pad electrode.

9. A setting method of a terminal capacitance of said pad electrode of said semiconductor device according to claim 6 which is capable of selectively setting said terminal capacitance, wherein cutting said surrounding wiring having said at least one second via at cutting positions set corresponding to a desired terminal capacitance so as to form a cut wiring portion electrically disconnected from said surrounding wiring and to be in a state in which said cut wiring portion and each said second via connected to said cut wiring portion are not connected to said external fixed potential.

10. A setting method of a terminal capacitance of said pad electrode of said semiconductor device according to claim 6 or 7 which is capable of selectively setting said terminal capacitance,
wherein forming a conductive region at a position set corresponding to a desired terminal capacitance in a plate layer under said surrounding wiring so that a via depth of said position of said conductive region is smaller than that of other regions in forming each said second via.
